(19) United States
(12) Patent Application Publication
(10) Pub. No.: US 2025/0022980 A1
(43) Pub. Date: Jan. 16, 2025

(54) CHEMICAL LIFT OFF DEVICE AND METHOD THEREOF

(71) Applicant: SAMSUNG ELECTRONICS CO., LTD., Suwon-si (KR)

(72) Inventors: Sanghoon SONG, Suwon-si (KR); Kyungwook HWANG, Suwon-si (KR); Junsik HWANG, Suwon-si (KR); Dongho KIM, Suwon-si (KR); Joonyong PARK, Suwon-si (KR); Youngtek OH, Suwon-si (KR); Minchul YU, Suwon-si (KR)

(73) Assignee: SAMSUNG ELECTRONICS CO., LTD., Suwon-si (KR)

(21) Appl. No.: 18/770,345

(22) Filed: Jul. 11, 2024

(30) Foreign Application Priority Data
Jul. 11, 2023 (KR) 10-2023-0090030

(51) Int. Cl. H01L 33/00

(52) U.S. Cl. CPC H01L 33/0093

(57) ABSTRACT

A chemical lift-off device includes a first chamber including a first bath containing a first chemical solution and configured to receive a semiconductor light-emitting device on a substrate, such that the semiconductor light-emitting device is partially separated from the substrate by being submerged in the first chemical solution, a cleaning bath containing deionized water and configured to receive the semiconductor light-emitting device that is partially separated from the substrate, and a second chamber including a separator including a chemical solution sprayer configured to spray a second chemical solution toward the semiconductor light-emitting device that is partially separated from the substrate, such that the semiconductor light-emitting device is completely separated from the substrate by being sprayed with the second chemical solution and a recovery assembly provided at a lower portion of the separator and configured to recover the semiconductor light-emitting device that is completely separated from the substrate.

### CROSS-REFERENCE TO RELATED APPLICATION

This application is based on and claims priority under 35 U.S.C. § 119 to Korean Patent Application No. 10-2023-0090030, filed on Jul. 11, 2023, in the Korean Intellectual Property Office, the disclosure of which is incorporated by reference herein in its entirety.

### BACKGROUND

### 1. Field

The disclosure relates to a lift-off device and a method thereof, and more particularly, to a chemical lift-off device for separating a semiconductor light-emitting device from a substrate using a chemical solution and a method thereof.

### 2. Description of the Related Art

Semiconductor light-emitting devices (LEDs) are high-efficiency, eco-friendly light sources and are used in various fields such as displays, optical communications, automobiles, and general lighting. Recently, with the development of white light LED technology, LED technology for general lighting has drawn great attention. White light LEDs may be manufactured, for example, by using blue or ultraviolet LEDs and phosphors, or a combination of red, green, and blue LEDs.

In order to manufacture an LED of a vertical structure for brightness improvement, it may be necessary to carry out a process of separating an epitaxially grown GaN-based LED thin film from a substrate, and in this process, a laser lift-off (LLO) process may be used. However, in the LLO process, as a laser is emitted, heat is applied to the GaN-based LED thin film above a critical sublimation temperature of gallium, which eventually may damage the GaN-based LED thin film, and thus, decrease the light output. In addition, gallium droplets remain in the GaN-based LED thin film after the separation of the substrate using a laser, and the gallium droplets must be removed through a subsequent process.

Recently, after epitaxially growing a GaN-based LED thin film using a silicon (Si) substrate instead of a sapphire substrate, a method of separating the GaN-based LED thin film from a silicon substrate by using a chemical lift-off process (CLO) has been proposed. However, when using a CLO, recovering a semiconductor light-emitting device is difficult.

### SUMMARY

Provided is a chemical lift-off device capable of efficiently performing chemical lift-off and recovering a semiconductor light-emitting device and a method thereof.

Additional aspects will be set forth in part in the description which follows and, in part, will be apparent from the description, or may be learned by practice of the presented embodiments of the disclosure.

According to an aspect of the disclosure, a chemical lift-off device may include a first chamber including a first bath containing a first chemical solution and configured to receive a semiconductor light-emitting device on a substrate, such that the semiconductor light-emitting device is partially separated from the substrate by being submerged in the first chemical solution, a cleaning bath containing deionized water and configured to receive the semiconductor light-emitting device that is partially separated from the substrate, and a second chamber including a separator including a chemical solution sprayer configured to spray a second chemical solution toward the semiconductor light-emitting device that is partially separated from the substrate, such that the semiconductor light-emitting device is completely separated from the substrate by being sprayed with the second chemical solution and a recovery assembly provided at a lower portion of the separator and configured to recover the semiconductor light-emitting device that is completely separated from the substrate.

The first bath may include a circulator configured to circulate the first chemical solution.

The first bath may include a temperature maintaining device configured to maintain a temperature of the first chemical solution.

The separator may include a deionized water sprayer configured to spray deionized water to remove the second chemical solution from the semiconductor light-emitting device.

The separator may include a fixing device configured to fix the substrate.

The recovery assembly may include a filter provided at a lower end of the separator.

The chemical lift-off device may include a first driver configured to move the semiconductor light-emitting device from the first bath to the cleaning bath.

The chemical lift-off device may include a second driver configured to move the semiconductor light-emitting device from the first chamber to the second chamber.

According to an aspect of the disclosure, a chemical lift-off method may include submerging a semiconductor light-emitting device on a substrate in a first chemical solution contained in a first bath of a first chamber such that the semiconductor light-emitting device is partially separated from the substrate in the first chamber, submerging the semiconductor light-emitting device on the substrate in deionized water contained in a cleaning bath of the first chamber, and spraying a second chemical solution in a separator of a second chamber and toward the semiconductor light-emitting device such that the semiconductor light-emitting device is completely separated from the substrate in the second chamber.

The method may include circulating the first chemical solution in the first bath of the first chamber.

The method may include recovering the semiconductor light-emitting device that is completely separated from the substrate by a recovery assembly of the second chamber.

The method may include spraying deionized water onto the semiconductor light-emitting device in the second chamber.

The method may include moving the semiconductor light-emitting device on the substrate from the first bath of the first chamber to the cleaning bath of the first chamber.

The method may include moving the semiconductor light-emitting device on the substrate from the first chamber to the second chamber.

The submerging of the semiconductor light-emitting device on the substrate in the first chemical solution contained in the first bath of the first chamber may be performed such that a sacrificial layer of the semiconductor light-emitting device is partially removed or the substrate is partially removed.

The submerging of the semiconductor light-emitting device on the substrate in the first chemical solution contained in the first bath of the first chamber may be performed for a period of time determined based on a size of the semiconductor light-emitting device.

According to an aspect of the disclosure, a chemical lift-off system may include a first bath containing a first chemical solution and configured to receive a semiconductor light-emitting device on a substrate and partially separate the semiconductor light-emitting device from the substrate by removing, with the first chemical solution, a first portion of a sacrificial layer between the semiconductor light-emitting device and the substrate, and a separator including a chemical solution sprayer, the separator configured to completely remove, from the substrate, the semiconductor light-emitting device that is partially separated from the substrate by receiving the semiconductor light-emitting device that is partially separated from the substrate and removing a second portion of the sacrificial layer between the semiconductor light-emitting device and the substrate by spraying, with the chemical solution sprayer, the semiconductor light-emitting device that is partially separated from the substrate with a second chemical solution.

The system may include a recovery assembly provided below the separator and including a filter, and the recovery assembly may be configured to recover the semiconductor light-emitting device that is completely removed from the substrate and pass, by the filter, materials that are less in size than the semiconductor light-emitting device.

The separator may include a fixing device configured to fix the substrate above the recovery assembly and at predetermined angle with respect to a ground as the second chemical solution is sprayed toward the substrate.

The first chemical solution and the second chemical solution may include a potassium hydroxide (KOH) solution.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a diagram of a chemical lift-off (CLO) device according to an embodiment;

FIGS. 2A to 2C are diagrams illustrating a CLO device according to an embodiment;

FIG. 3 is a diagram of a CLO device according to an embodiment;

FIG. 4 is a diagram illustrating CLO performed in a bath of a first chamber, according to an embodiment;

FIGS. 5 and 6 are diagrams illustrating a CLO performed in a separator of a second chamber, according to an embodiment;

FIG. 7 is a diagram illustrating an example of a CLO device according to an embodiment;

FIGS. 8 to 10 are diagrams illustrating a transfer process using fluidic self-assembly (FSA) technology, according to an embodiment;

FIGS. 11 to 15 are diagrams illustrating a display manufacturing process according to an embodiment;

FIG. 16 is a flowchart illustrating a CLO method according to an embodiment;

FIG. 17 is a flowchart illustrating a method of performing CLO according to an embodiment; and

FIG. 18 is a flowchart illustrating a method of performing CLO method according to an embodiment.

### DETAILED DESCRIPTION

Reference will now be made in detail to embodiments, examples of which are illustrated in the accompanying drawings, where like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, a chemical lift-off device and a method of operating the same according to various embodiments will be described in detail with reference to the accompanying drawings. In the following drawings, like reference numerals refer to like components, and the size of each component in the drawings may be exaggerated for clarity and convenience of description. The terms “first” and “second”, etc., may be used herein to describe various elements, these elements should not be limited by these terms. These terms are only used to distinguish one component from another.

The singular forms include the plural forms unless the context clearly indicates otherwise. In addition, when a portion “includes” an element, another element may further be included, rather than excluding the existence of the other element, unless otherwise described. In addition, the size or height of each component in the drawings may be exaggerated for clarity of explanation. Also, when it is described that a predetermined material layer is present on a substrate or another layer, the material layer may present in direct contact with the substrate or other layer, and another third layer may exist therebetween. In addition, because materials constituting each layer in the following examples are examples, other materials may also be included.

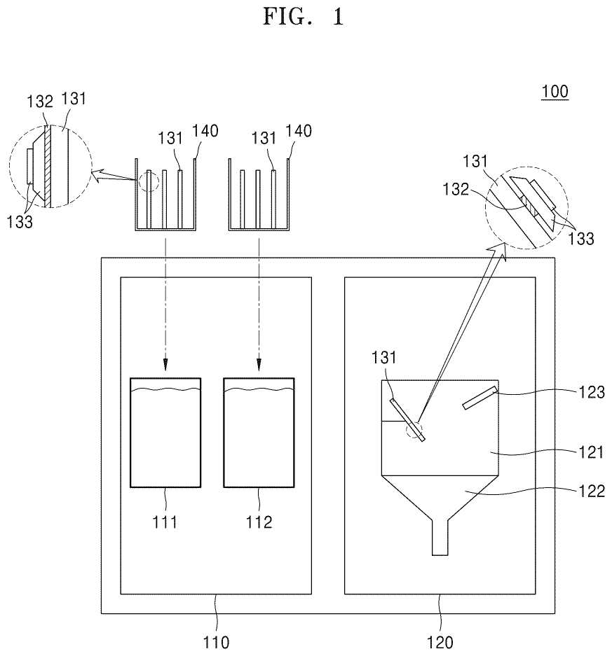

FIG. 1 is a diagram of a chemical lift-off (CLO) device 100 according to an embodiment.

Referring to FIG. 1, the CLO device 100 according to an embodiment may include a first chamber 110 and a second chamber 120. The first chamber 110 may include a first bath 111 and a cleaning bath 112, and the second chamber 120 may include a separator 121 and a recovery assembly 122. In the CLO device 100, substrates (or wafers) 131 having semiconductor light-emitting devices 133 to undergo lift-off processing may be mounted on a cassette 140.

The substrates 131 mounted on the cassette 140 may be moved to the first bath 111 of the first chamber 110. The first bath 111 contains a chemical solution. The chemical solution may be, for example, a potassium hydroxide (KOH) solution. In the first bath 111, the substrates 131 having the semiconductor light-emitting devices 133 may be submerged into the chemical solution. In the first bath 111, a sacrificial layer 132 provided between the substrate 131 and the semiconductor light-emitting device 133 may be partially removed by a chemical reaction with the chemical solution (e.g., a first portion of the sacrificial layer 132 may be removed). The sacrificial layer 132 is a layer that may be selectively removed when a CLO is performed, and is a thin film layer preferentially formed before manufacturing the semiconductor light-emitting device 133. For example, in the first bath 111, about 80% to about 90% of the original volume of the sacrificial layer 132 may be removed. By removing only a portion of the sacrificial layer 132, a CLO submerging process time may be reduced. To this end, the time during which the semiconductor light-emitting device 133 is submerged in the chemical solution in the first bath 111 may be adjusted according to the size of the semiconductor light-emitting device 133. For example, when the size of the semiconductor light-emitting device 133 is about 10 μm, the semiconductor light-emitting device 133 may be submerged in the first bath 111 for about 1 hour. When the size of the semiconductor light-emitting device 133 is about 20 μm, the semiconductor light-emitting device 133 may be submerged in the first bath 111 for about 2 hours. When the size of the semiconductor light-emitting device 133 is about 40 μm, the semiconductor light-emitting device 133 may be deposited in the first bath 111 for about 4 hours. The size of the semiconductor light-emitting device 133 indicates the maximum diameter of a cross section of the semiconductor light-emitting device 133, and the settling time of the semiconductor light-emitting device 133 may be determined in proportion to the size of the semiconductor light-emitting device 133. The cross-section indicates a cross-section perpendicular to a direction in which light is emitted from the semiconductor light-emitting device 133. In the first chamber 110, the semiconductor light-emitting device 133 may be controlled such that it is not completely separated from the substrate 131 (i.e., the semiconductor light-emitting device 133 may be partially separated from the substrate 131). That is, the sacrificial layer 132 provided between the substrate 131 and the semiconductor light-emitting device 133 may not be completely removed but may remain partially. Hereinafter, the semiconductor light-emitting device 133 that is not completely separated from the substrate 131 but remain partially may be referred to as a partially separated semiconductor light-emitting device 133. In the first bath 111, a batch type process in which a plurality of substrates 131 having a plurality of semiconductor light-emitting devices 133 are submerged in a chemical solution may be performed.

In another embodiment, when the substrate 131 is a silicon substrate, the silicon substrate itself may function as the role of the sacrificial layer 132. That is, in this case, the substrate 131 may be partially removed in the first bath 111 of the first chamber 110.

The cleaning bath 112 contains deionized water (or ultra-pure water). In the cleaning bath 112, the substrates 131 having the semiconductor light-emitting devices 133 may be submerged in the deionized water. In the cleaning bath 112, contaminants attached to the partially separated semiconductor light-emitting device 133 may be removed. In the cleaning bath 112, a batch process in which the plurality of substrates 131 having the plurality of semiconductor light-emitting devices 133 are submerged in the deionized water may be performed.

The semiconductor light-emitting device 133 from which contaminants are removed in the cleaning bath 112 of the first chamber 110 may be moved to the separator 121 of the second chamber 120. The semiconductor light-emitting device 133 moved to the separator 121 of the second chamber 120 may still be partially separated from the substrate 131. In the separator 121, a chemical solution sprayer 123 may spray the chemical solution toward the semiconductor light-emitting device 133 that is partially separated from the substrate 131. In the separator 121, the sacrificial layer 132 provided between the substrate 131 and the semiconductor light-emitting device 133 may be completely removed by a chemical reaction with the chemical solution. Thus, the substrate 131 and the semiconductor light-emitting device 133 may be separated in the separator 121. In the separator 121, chemical solution spraying may be performed on the individual substrates 131.

The semiconductor light-emitting device 133 separated from the substrate 131 may be recovered in the recovery assembly 122.

That is, the semiconductor light-emitting device 133 provided on the substrate 131 may be partially separated from the substrate 131 in the first chamber 110, and the semiconductor light-emitting device 133 that is partially separated from the substrate 131 may be completely separated from the substrate 131 in the second chamber 120.

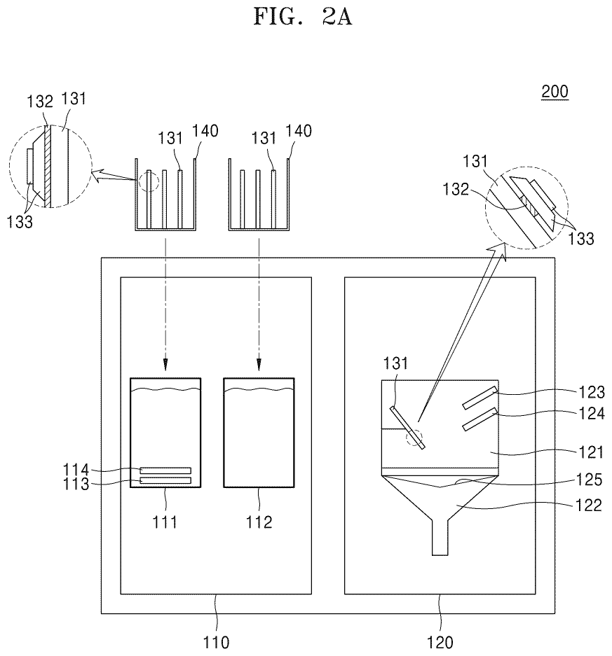

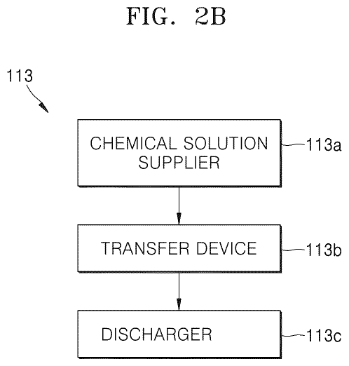

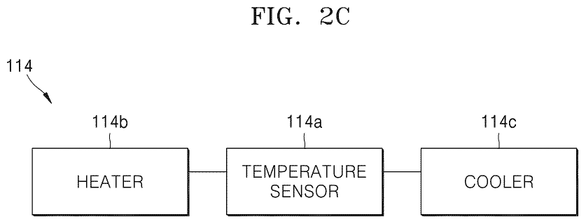

FIGS. 2A to 2C are diagrams illustrating a chemical lift-off device 200 according to an embodiment. Hereinafter, differences from the chemical lift-off device 100 of FIG. 1 will be mainly described.

Referring to FIG. 2A, the first bath 111 of the first chamber 110 may include a circulator 113 and a temperature maintaining device 114. The circulator 113 may circulate the chemical solution contained in the first bath 111 of the first chamber 110. Referring to FIG. 2B, the circulator 113 may include, for example, a chemical solution supplier 113a for supplying a chemical solution to the first bath 111, a transfer device 113b for supplying a solution of the chemical solution supplier 113a to the first bath 111, and a discharger 113c for discharging the chemical solution of the first bath 111. The temperature maintaining device 114 may maintain a constant temperature of the chemical solution contained in the first bath 111 of the first chamber 110. Referring to FIG. 2C, the temperature maintaining device 114 may include, for example, a temperature sensor 114a, a heater 114b, and a cooler 114c. The temperature maintaining device 114 may maintain, for example, the temperature of the chemical solution contained in the first bath 111 of the first chamber 110 between about 30° C. and about 60° C. In FIG. 2A, although it is depicted that the circulator 113 and the temperature maintenance device 114 are provided inside the first chamber 110, the circulator 113 and the temperature maintenance device 114 may be provided outside the first chamber 110.

A deionized water sprayer 124 may be provided in the separator 121 of the second chamber 120. The deionized water sprayer 124 provided in the separator 121 may spray deionized water onto the fixed substrate 131 to remove the chemical solution and contaminants remaining in the semiconductor light-emitting device 133. In addition to the spray injection method, deionized water may be supplied in various ways to remove the chemical solution and contaminants remaining in the semiconductor light-emitting device 133.

The recovery assembly 122 may include a filter (or wiper) 125. The filter 125 may include, for example, a nylon mesh or laboratory filter paper. The wiper may include, for example, a microfiber wiper. The filter 125 of the recovery assembly 122 may pass materials less in size than the semiconductor light-emitting device 133. The chemical solution, deionized water, contaminants, etc. may be discharged to the outside through the filter 125 of the recovery assembly 122. The filter 125 of the recovery assembly 122 may be detachable and replaceable. Above the filter 125 of the recovery assembly 122, the separated semiconductor light-emitting device 133 may be filtered. The filter 125 of the recovery assembly 122 is dried, and the semiconductor light-emitting devices 133 may be collected in the center of the filter 125 while spraying ethanol on one side of the filter 125 where the semiconductor light-emitting devices 133 are gathered. The CLO process may be completed by collecting the semiconductor light-emitting devices 133 while spraying ethanol on a side opposite to the one side of the filter 125.

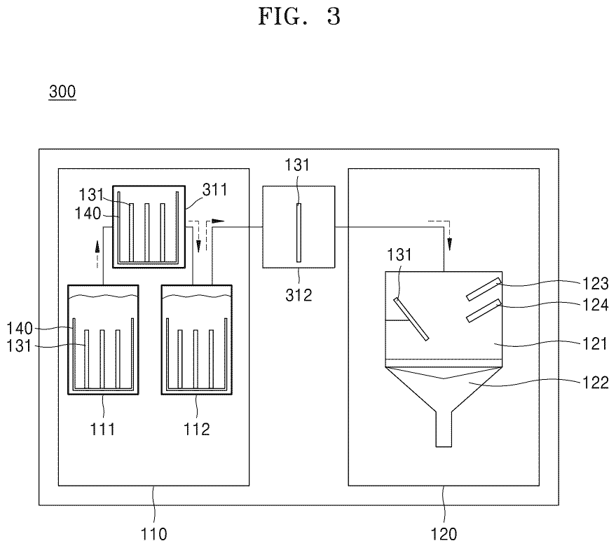

FIG. 3 is a diagram of a CLO device 300 according to an embodiment. Hereinafter, differences from the CLO devices 100 and 200 of FIGS. 1 and 2A will be mainly described.

Referring to FIG. 3, a first driver 311 may include an automatic transfer device (e.g., a robot arm). In the first bath 111 of the first chamber 110, the semiconductor light-emitting device 133 is partially separated from the substrate 131, and the semiconductor light-emitting device 133 remaining on the substrate 131 may be moved to the cleaning bath 112 by the first driver 311. The first driver 311 may move the cassette 140 on which the substrate (or wafer) 131 is mounted in the first bath 111 of the first chamber 110 to the cleaning bath 112.

The semiconductor light-emitting device 133 provided on the substrate 131 from which a contamination source is removed in the cleaning bath 112 of the first chamber 110 is moved to the separator 121 of the second chamber 120 by a second driver 312. The second driver 312 may include an automatic transfer device (e.g., a robot arm).

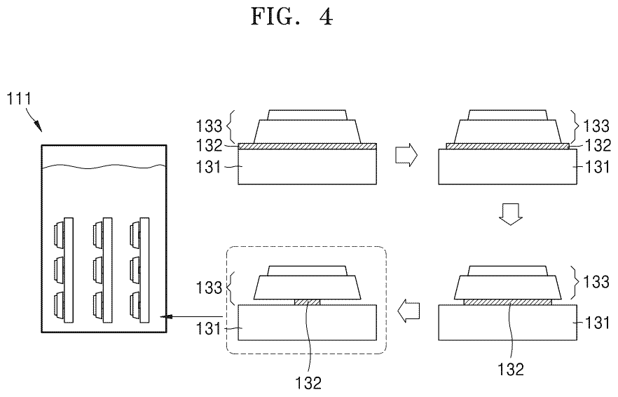

FIG. 4 is a diagram illustrating CLO performed in the first bath 111 of the first chamber 110 according to an embodiment. In FIG. 4, like reference numerals are used to indicate elements that are substantially identical to the elements of FIG. 1.

Referring to FIG. 4, the sacrificial layer 132 may be provided between the substrate 131 and the semiconductor light-emitting device 133. The semiconductor light-emitting device 133 may include, for example, a micro-light-emitting diode (LED). The sacrificial layer 132 may be partially removed in the first bath 111 of the first chamber 110.

The sacrificial layer 132 is a layer that may be selectively removed when CLO is performed and is a thin film layer that may be formed before manufacturing the semiconductor light-emitting device 133. When the substrate 131 is a silicon substrate, the silicon substrate itself may replace the role of the sacrificial layer 132. That is, in this case, the substrate 131 may be partially removed in the first bath 111 of the first chamber 110.

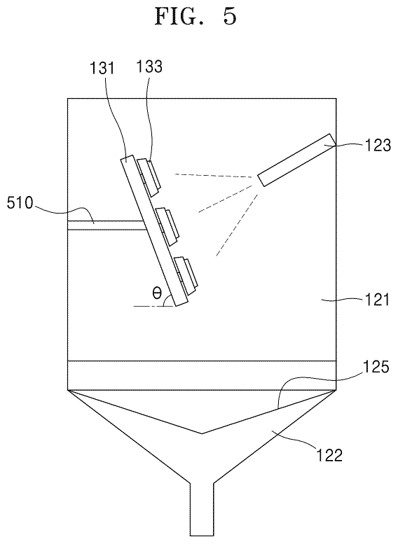

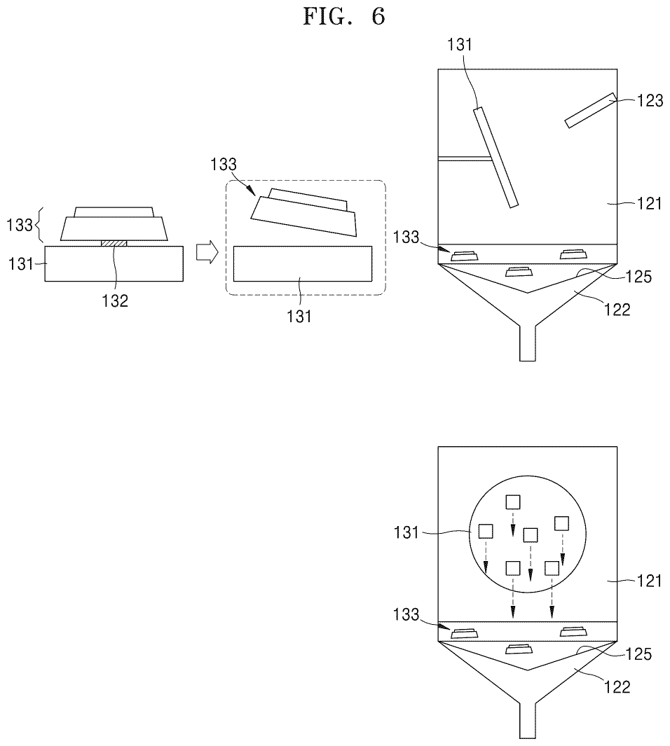

FIGS. 5 and 6 are diagrams illustrating a CLO performed in the separator 121 of the second chamber 120 according to an embodiment. In FIGS. 5 and 6, like reference numerals are used to indicate elements that are substantially identical to the elements of FIG. 1.

Referring to FIG. 5, in the separator 121 of the second chamber 120, the chemical solution sprayer 123 may spray the chemical solution toward partially separated semiconductor light-emitting devices 133. The separator 121 may include a fixing device 510 for fixing the substrate 131 having the semiconductor light-emitting device 133 at a predetermined angle with the ground. The fixing device 510 may be, for example, a jig. The fixing device 510 may fix the substrate 131 to form a certain angle θ with the ground. The substrate 131 may be fixed to form an angle in a range of about 60 degrees to about 80 degrees with the ground. In the separator 121, the chemical solution sprayer 123 may spray the chemical solution to the fixed substrate 131. The chemical solution sprayed from the chemical solution sprayer 123 may remove the remaining sacrificial layer 132 while flowing down from the substrate 131.

Referring to FIG. 6, in the separator 121, the sacrificial layer 132 provided between the substrate 131 and the semiconductor light-emitting device 133 may be completely removed through a chemical reaction with the chemical solution. In the separator 121, the substrate 131 and the semiconductor light-emitting device 133 may be separated. When the remaining sacrificial layer 132 is removed, the semiconductor light-emitting device 133 separated from the substrate 131 may fall into the filter 125 provided under the separator 121.

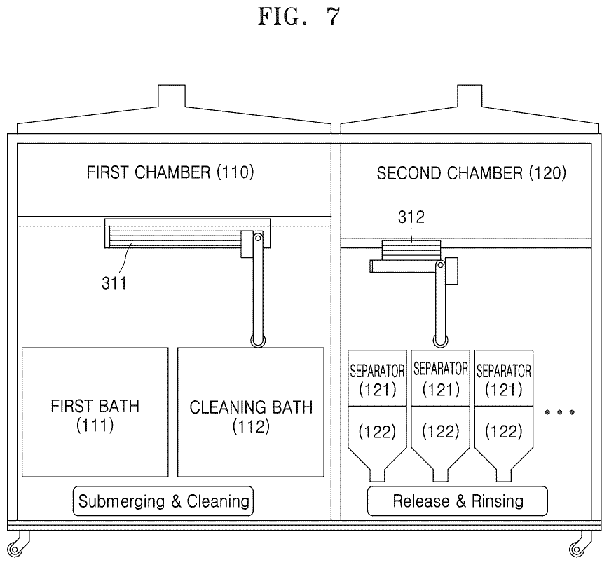

FIG. 7 is a diagram illustrating an example of a CLO device according to an embodiment.

In FIGS. 1 to 6, one separator 121 and one recovery assembly 122 are shown in the second chamber 120, but a plurality of separators 121 and a plurality of recovery assemblies 122 may be provided in the second chamber 120. In addition, various embodiments may be possible as needed.

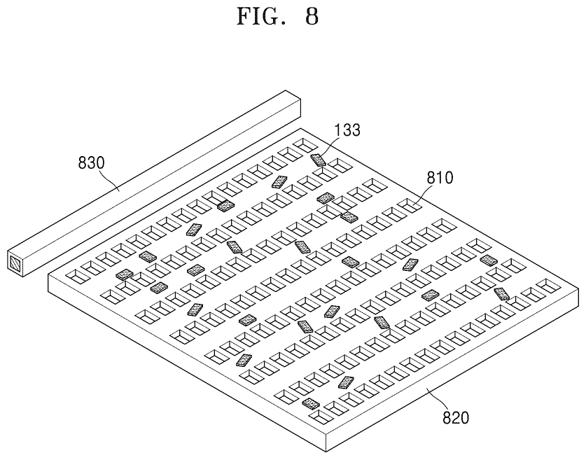

FIGS. 8 to 10 are diagrams illustrating a transfer process using a fluidic self-assembly (FSA) technology according to an embodiment. The semiconductor light-emitting device 133 of FIGS. 8 to 10 may be the CLO device described with reference to FIGS. 1 to 7.

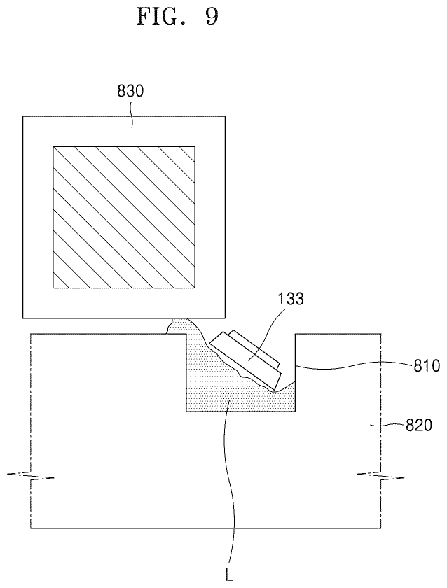

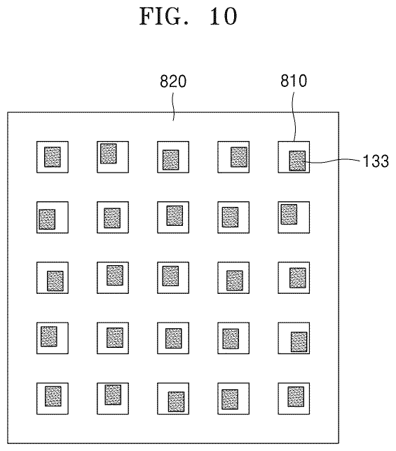

As shown in FIG. 8, the plurality of semiconductor light-emitting devices 133 recovered from the recovery assembly 122 of the second chamber 120 may be moved onto a mold substrate 820 provided with grooves 810. As shown in FIG. 9, a transport fluid L may be supplied to the mold substrate 820 and an upper surface of the mold substrate 820 may be wiped using a wiper 830. As shown in FIG. 10, the semiconductor light-emitting devices 133 may be transferred to the mold substrate 820 through a fluid self-assembly method.

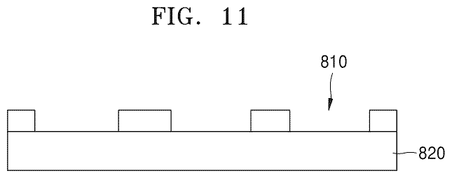

FIGS. 11 to 15 are diagrams illustrating a display manufacturing process according to an embodiment. The mold substrate 820 of FIGS. 11 to 15 may be identical to or similar to the mold substrate 820 of FIGS. 8 to 10, and the semiconductor light-emitting device 133 of FIGS. 11 to 15 may be the CLO device described with reference to FIGS. 1 to 7. The semiconductor light-emitting device 133 may include, for example, a micro-LED.

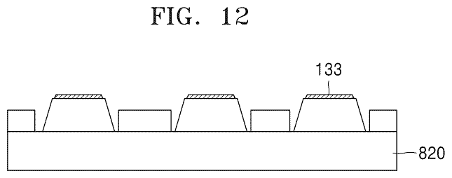

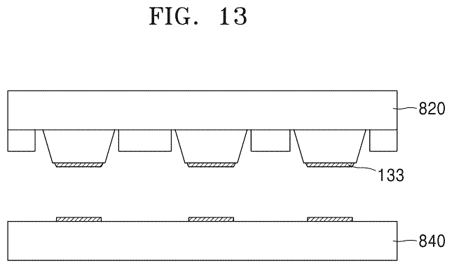

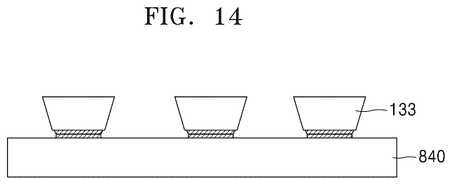

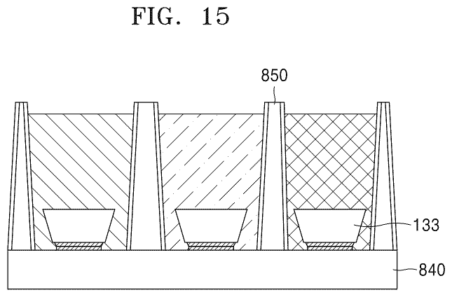

Referring to FIG. 11, the mold substrate 820 on which a semiconductor light-emitting device is to be disposed may be provided. Referring to FIG. 12, the semiconductor light-emitting device 133 may be transferred onto the mold substrate 820. Referring to FIG. 13, a display substrate 840 to which the semiconductor light-emitting device 133 will be transferred may be provided. Referring to FIG. 14, the semiconductor light-emitting device 133 may be transferred to the display substrate 840 through bonding. Referring to FIG. 15, a display may be manufactured by performing color conversion of each semiconductor light-emitting device 133 and forming a barrier 850 between pixels.

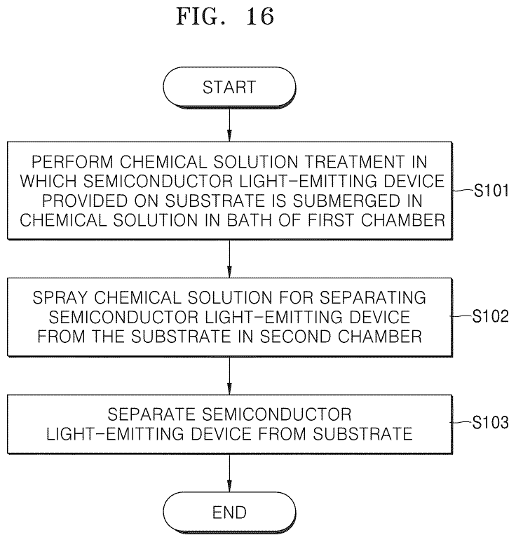

FIG. 16 is a flowchart illustrating a CLO method according to an embodiment. The CLO method will be described with reference to FIG. 1.

Referring to FIG. 16, the CLO method according to an embodiment may include, in operation S101, performing a chemical solution treatment in which the semiconductor light-emitting device 133 provided on the substrate 131 is submerged in the chemical solution in the first bath 111 of the first chamber 110 containing the chemical solution. The sacrificial layer 132 provided between the substrate 131 and the semiconductor light-emitting device 133 may be partially removed by a chemical reaction with the chemical solution in the first bath 111 of the first chamber 110. For example, in the first bath 111, about 80% to about 90% of the original volume of the sacrificial layer 132 may be removed. To this end, the time during which the semiconductor light-emitting device 133 is submerged in the chemical solution in the first bath 111 may be adjusted. The above-described chemical solution may include, for example, a KOH solution. A batch type process in which the plurality of substrates 131 having the plurality of semiconductor light-emitting devices 133 are submerged in the chemical solution may be performed in the first bath 111.

In another embodiment, when the substrate 131 is a silicon substrate, the silicon substrate itself may replace the role of the sacrificial layer 132. In this case, a portion of the substrate 131 may be removed in the first bath 111 of the first chamber 110.

After the chemical solution treatment is performed in the first bath 111 of the first chamber 110, the CLO method according to an embodiment may include, in operation S102, spraying the chemical solution onto the semiconductor light-emitting device 133 to separate the semiconductor light-emitting device 133 from the substrate 131 in the separator 121 of the second chamber 120. The chemical solution sprayer 123 may spray the chemical solution onto the partially separated semiconductor light-emitting device 133 in the separator 121.

In the separator 121 of the second chamber 120, in operation S103, the substrate 131 and the semiconductor light-emitting device 133 may be completely separated by spraying a chemical solution for separating the semiconductor light-emitting device 133 provided on the substrate 131 from the substrate 131. In the separator 121, the sacrificial layer 132 provided between the substrate 131 and the semiconductor light-emitting device 133 may be completely removed by a chemical reaction with the chemical solution.

In another embodiment, when the substrate 131 is a silicon substrate, the silicon substrate itself may replace the role of the sacrificial layer 132. In this case, the substrate 131 may be completely removed in the separator 121 of the second chamber 120.

That is, the semiconductor light-emitting device 133 provided on the substrate 131 may be partially separated from the substrate 131 in the first chamber 110, and the semiconductor light-emitting device 133 that is partially separated from the substrate 131 may be completely separated from the substrate 131 in the second chamber 120.

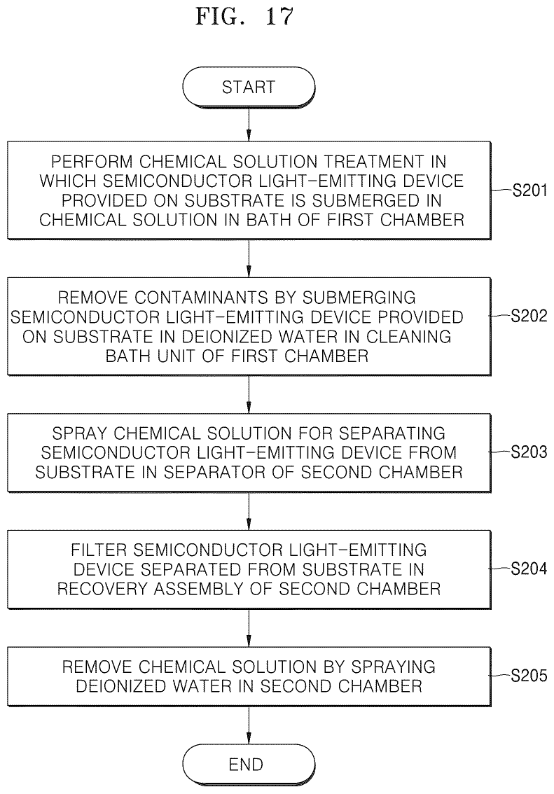

FIG. 17 is a flowchart illustrating a CLO method according to an embodiment. FIG. 17 will be described with reference to FIG. 3.

Referring to FIG. 17, the CLO method according to an embodiment may include, operation S201, performing a chemical solution treatment in which the semiconductor light-emitting device 133 provided on the substrate 131 is submerged in the chemical solution for partially separating the semiconductor light-emitting device 133 from the substrate 131 in the first bath 111 of the first chamber 110. In operation S202, in the cleaning bath 112 of the first chamber 110, the semiconductor light-emitting device 133 provided on the substrate 131 may be submerged in deionized water to remove contaminants. In this case, a batch type process in which the plurality of substrates 131 having the plurality of semiconductor light-emitting devices 133 are submerged in deionized water may be performed in the cleaning bath 112.

After the semiconductor light-emitting device 133 provided on the substrate 131 is submerged in deionized water in the cleaning bath 122 of the first chamber 110, in operation S203, the substrate 131 and the semiconductor light-emitting device 133 may be completely separated by spraying a chemical solution to separate the semiconductor light-emitting device 133 from the substrate 131 in the separator 121 of the second chamber 120. Chemical solution spraying may be performed onto the individual substrates 131 in the separator 121.

In operation S204, in the separator 121 of the second chamber 120, the semiconductor light-emitting device 133 that is completely separated from the substrate 131 may fall, and the separated semiconductor light-emitting device 133 may be collected by filtering in the filter 125 provided in the recovery assembly 122. The filter 125 of the recovery assembly 122 may pass materials less in size than the semiconductor light-emitting device 133. The separated semiconductor light-emitting device 133 may be filtered on the filter 125 of the recovery assembly 122. The chemical solution, deionized water, contaminants, etc. may be discharged to the outside through the filter 125 of the recovery assembly 122.

In operation S205, the deionized water sprayer 124 of the second chamber 120 sprays deionized water to the semiconductor light-emitting device 133 recovered by filtering in the recovery assembly 122 of the second chamber 120 to remove the chemical solution.

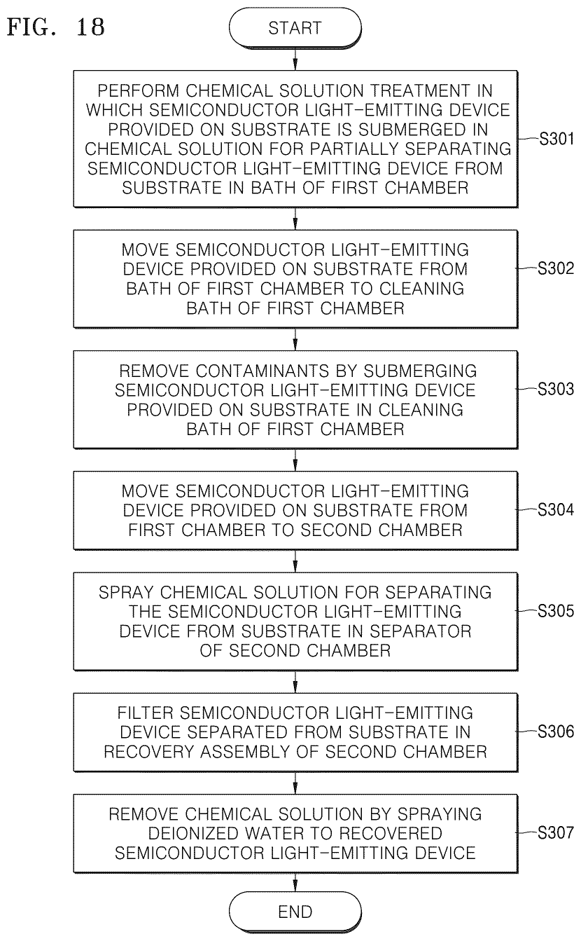

FIG. 18 is a flowchart illustrating a CLO method according to an embodiment. FIG. 18 will be described with reference to FIG. 3.

Referring to FIG. 18, the CLO method according to an embodiment may include, in operation S301, performing a chemical solution treatment in which the semiconductor light-emitting device 133 provided on the substrate 131 is submerged in the chemical solution for partially separating the semiconductor light-emitting device 133 from the substrate 131 in the first bath 111 of the first chamber 110.

After the chemical solution treatment is performed in the first chamber 110, in operation S302, the semiconductor light-emitting device 133 may be partially separated from the substrate 131 in the first bath 111 of the first chamber 110, and the semiconductor light-emitting device remaining on the substrate 131 may be moved to the cleaning bath 112 by the first driver 311. The first driver 311 may move the cassette 140 on which the substrate 131 is mounted from the first bath 111 of the first chamber 110 to the cleaning bath 112.

After moving the semiconductor light-emitting device 133 provided on the substrate 131 moved to the cleaning bath 112 of the first chamber 110 to the cleaning bath 112 of the first chamber 110, in the cleaning bath 112 of the first chamber 110, in operation S303, the semiconductor light-emitting device 133 provided on the substrate 131 may be submerged in deionized water to remove contaminants. In this case, a batch type process in which the plurality of substrates 131 having the plurality of semiconductor light-emitting devices 133 are submerged in deionized water may be performed in the cleaning bath 112.

After removing contaminants by submerging the semiconductor light-emitting device 133 provided on the substrate 131 in deionized water in the cleaning bath 112 of the first chamber 110, in operation S304, the second driver 312 may move the semiconductor light-emitting device 133 provided on the substrate 131 from the first chamber 110 to the separator 121 of the second chamber 120.

After moving the semiconductor light-emitting device 133 provided on the substrate 131 to the separator 121 of the second chamber 120, in operation S305, the substrate 131 and the semiconductor light-emitting device 133 may be completely separated by spraying a chemical solution for separating the semiconductor light-emitting device 133 from the substrate 131 in the separator 121 of the second chamber 120.

In operation S306, in the separator 121 of the second chamber 120, the semiconductor light-emitting device 133 completely separated from the substrate 131 may fall, and the fallen semiconductor light-emitting device 133 may be collected by filtering in the filter 125 provided in the recovery assembly 122. The filter 125 of the recovery assembly 122 may pass materials less in size than the semiconductor light-emitting device 133. The separated semiconductor light-emitting device 133 may be filtered on the filter 125 of the recovery assembly 122. The chemical solution, deionized water, contaminants, etc. may be discharged to the outside through the filter 125 of the recovery assembly 122. The filter 125 provided in the recovery assembly 122 of the second chamber 120 may include a wiper to collect the semiconductor light-emitting devices 133 in one place.

In operation S307, the deionized water sprayer 124 of the second chamber 120 sprays deionized water to the semiconductor light-emitting device 133 recovered by filtering in the recovery assembly 122 of the second chamber 120 to remove the chemical solution.

The CLO device and method described above may shorten the CLO submerging process time by dividing the CLO process in the first chamber 110 and the second chamber 120, and it is easy to recover a large amount of semiconductor light-emitting devices. Also, contaminants of the semiconductor light-emitting device may be effectively removed.

A CLO device and method according to various embodiments perform CLO separately in a first chamber and a second chamber, thereby reducing process time, removing residual contamination sources, and enabling recovery of a large amount of chips.

A CLO device and method have been described with reference to the embodiments shown in the drawings to facilitate understanding. However, it will be understood by those of ordinary skill in the art that various changes in form and details may be made therein without departing from the spirit and scope of the disclosure. Therefore, the true technical protection scope of the CLO device and method of the disclosure should be defined by the appended claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A chemical lift-off device comprising:
a first chamber comprising:
a first bath containing a first chemical solution and configured to receive a semiconductor light-emitting device on a substrate, such that the semiconductor light-emitting device is partially separated from the substrate by being submerged in the first chemical solution; and
a cleaning bath containing deionized water and configured to receive the semiconductor light-emitting device that is partially separated from the substrate; and
a second chamber comprising:
a separator comprising a chemical solution sprayer configured to spray a second chemical solution toward the semiconductor light-emitting device that is partially separated from the substrate, such that the semiconductor light-emitting device is completely separated from the substrate by being sprayed with the second chemical solution; and
a recovery assembly provided at a lower portion of the separator and configured to recover the semiconductor light-emitting device that is completely separated from the substrate.

2. The chemical lift-off device of claim 1, wherein the first bath comprises a circulator configured to circulate the first chemical solution.

3. The chemical lift-off device of claim 1, wherein the first bath comprises a temperature maintaining device configured to maintain a temperature of the first chemical solution.

4. The chemical lift-off device of claim 1, wherein the separator further comprises a deionized water sprayer configured to spray deionized water to remove the second chemical solution from the semiconductor light-emitting device.

5. The chemical lift-off device of claim 1, wherein the separator further comprises a fixing device configured to fix the substrate.

6. The chemical lift-off device of claim 1, wherein the recovery assembly comprises a filter provided at a lower end of the separator.

7. The chemical lift-off device of claim 1, further comprising a first driver configured to move the semiconductor light-emitting device from the first bath to the cleaning bath.

8. The chemical lift-off device of claim 7, further comprising a second driver configured to move the semiconductor light-emitting device from the first chamber to the second chamber.

9. A chemical lift-off method, comprising:
submerging a semiconductor light-emitting device on a substrate in a first chemical solution contained in a first bath of a first chamber such that the semiconductor light-emitting device is partially separated from the substrate in the first chamber;
submerging the semiconductor light-emitting device on the substrate in deionized water contained in a cleaning bath of the first chamber; and
spraying a second chemical solution in a separator of a second chamber and toward the semiconductor light-emitting device such that the semiconductor light-emitting device is completely separated from the substrate in the second chamber.

10. The chemical lift-off method of claim 9, further comprising circulating the first chemical solution in the first bath of the first chamber.

11. The chemical lift-off method of claim 9, further comprising recovering the semiconductor light-emitting device that is completely separated from the substrate by a recovery assembly of the second chamber.

12. The chemical lift-off method of claim 9, further comprising spraying deionized water onto the semiconductor light-emitting device in the second chamber.

13. The chemical lift-off method of claim 9, further comprising moving the semiconductor light-emitting device on the substrate from the first bath of the first chamber to the cleaning bath of the first chamber.

14. The chemical lift-off method of claim 9, further comprising moving the semiconductor light-emitting device on the substrate from the first chamber to the second chamber.

15. The chemical lift-off method of claim 9, wherein the submerging of the semiconductor light-emitting device on the substrate in the first chemical solution contained in the first bath of the first chamber is performed such that a sacrificial layer of the semiconductor light-emitting device is partially removed or the substrate is partially removed.

16. The chemical lift-off method of claim 9, wherein the submerging of the semiconductor light-emitting device on the substrate in the first chemical solution contained in the first bath of the first chamber is performed for a period of time determined based on a size of the semiconductor light-emitting device.

17. A chemical lift-off system, comprising:
a first bath containing a first chemical solution and configured to receive a semiconductor light-emitting device on a substrate and partially separate the semiconductor light-emitting device from the substrate by removing, with the first chemical solution, a first portion of a sacrificial layer between the semiconductor light-emitting device and the substrate; and
a separator comprising a chemical solution sprayer, the separator configured to completely remove, from the substrate, the semiconductor light-emitting device that is partially separated from the substrate by:
receiving the semiconductor light-emitting device that is partially separated from the substrate; and
removing a second portion of the sacrificial layer between the semiconductor light-emitting device and the substrate by spraying, with the chemical solution sprayer, the semiconductor light-emitting device that is partially separated from the substrate with a second chemical solution.

18. The chemical lift-off system of claim 17, further comprising:
a recovery assembly provided below the separator and comprising a filter,
wherein the recovery assembly is configured to recover the semiconductor light-emitting device that is completely removed from the substrate and pass, by the filter, materials that are less in size than the semiconductor light-emitting device.

19. The chemical lift-off system of claim 18, wherein the separator further comprises a fixing device configured to fix the substrate above the recovery assembly and at predetermined angle with respect to a ground as the second chemical solution is sprayed toward the substrate.

20. The chemical lift-off system of claim 17, wherein the first chemical solution and the second chemical solution comprise a potassium hydroxide (KOH) solution.
